(19) United States
(12) Patent Application Publication
(10) Pub. No.: US 2001/0052635 A1
(43) Pub. Date: Dec. 20, 2001

(54) Semiconductor integrated circuit device

(75) Inventor: Tetsuya Takayama, Osaka (JP)

Correspondence Address: PARKHURST & WENDEL, L.L.P., Suite 210, 1421 Prince Street, Alexandria, VA, 22314-2805, US

(73) Assignee: MATSUSHITA ELECTRIC INDUSTRIAL CO., LTD.

(21) Appl. No.: 09/879,120

(22) Filed: Jun. 13, 2001

(30) Foreign Application Priority Data
Jun. 20, 2000 (JP) 2000-183862

(51) Int. Cl. H01L 23/544

(52) U.S. Cl. 257/620

(57) ABSTRACT

To provide an evaluation chip which can eliminate the need for developing a microcomputer for mass production in addition to an evaluation chip and operate at high speeds without any limits on a chip size and the number of terminals. A microcomputer and a microcomputer scribed line are provided therein and wiring is not performed on the microcomputer on the evaluation chip. Since the microcomputer can be cut from the evaluation chip, it is not necessary to develop a microcomputer separately. Additionally, since an internal signal of the microcomputer is drawn using a glass substrate, the evaluation chip is applicable as an emulator module.

### FIELD OF THE INVENTION

The present invention relates to a semiconductor integrated circuit device which includes semiconductor integrated circuits having a plurality of independent functions mounted therein. Such a device is typified by an evaluation chip and the like, which integrates a microcomputer and an emulation part for checking the microcomputer.

### BACKGROUND OF THE INVENTION

A conventional art will be described by taking an evaluation chip as an example.

U.S. Pat. No. 4,833,620 discloses a manufacturing method of an evaluation chip of a 1-chip microcomputer, in which an using efficiency of a chip region is improved by simplifying a wiring in the evaluation chip to eliminate incorrect connection of the wiring. This method is a manufacturing method of an evaluation chip for a mass-produced 1-chip microcomputer. The following will discuss the outline.

An expansion region is provided around a device region for a 1-chip microcomputer. The device region includes circuits other than a ROM, and first bonding pads are disposed in an array around the region and are connected to the circuits. An interface is formed in a region where the ROM is removed in the device region, and the evaluation chip can have access to an external memory device. Second bonding pads whose number is equivalent to the first bonding pads and the interface are provided around the expansion region. The second bonding pads are disposed in an array with substantially equal pitches. Additional wiring is provided for making connection to the second bonding pads which correspond to the first bonding pads and the interface. When a multilayer wiring technique is adopted for the evaluation chip, the second bonding pads and the wiring connecting to the second bonding pads are formed on the highest wiring layer.

Further, FIG. 2 shows the configuration of a conventional evaluation chip, which is different from the above example. In FIG. 2, reference numeral 1 denotes an evaluation chip, reference numeral 2 denotes a microcomputer included in the evaluation chip 1, reference numeral 4 denotes emulation parts which are connected to internal signals of the microcomputer 2 included in the evaluation chip 1, reference numeral 5 denotes microcomputer I/O pads which are I/O pads of the microcomputer 2, and reference numeral 8 denotes evaluation chip I/O pads which are I/O pads of the evaluation chip 1 connected to the microcomputer I/O pads 5.

The following will discuss the evaluation chip having the above configuration.

First, the microcomputer 2 is laid out separately. Subsequently, the emulation parts 4 are disposed around the separate layout of the microcomputer 2. Next, internal signals of the microcomputer 2 and the emulation parts 4 are connected to each other. And then, the evaluation chip I/O pads 8 are disposed and are connected to the microcomputer I/O pads 5, and layout is performed entirely on the evaluation chip 1. Finally, the evaluation chip 1 is formed using the entire layout. Hence, the evaluation chip 1 can input and output a signal to the microcomputer I/O pads 5 via the evaluation chip I/O pads 8. Moreover, since the emulation parts 4 are connected to internal signals of the microcomputer 2, it is possible to monitor and control internal signals of the microcomputer 2, and emulation can be performed on the microcomputer 2.

FIGS. 3 and 4 show the configurations of conventional emulator modules each using the single microcomputer 2.

In FIG. 3, reference numeral 2 denotes a microcomputer for mass production, reference numeral 5 denotes microcomputer I/O pads which are I/O pads of the microcomputer 2, reference numeral 6 denotes internal signal pads allowing input and output of internal signals of the microcomputer 2, reference numeral 11 denotes a glass substrate for mounting the microcomputer 2, reference numeral 12 denotes a glass substrate I/O pad disposed around the glass substrate 11, reference numeral 13 denotes microcomputer I/O corresponding pads which correspond to the microcomputer I/O pads 5 and are wired to the glass substrate I/O pad 12, reference numeral 14 denotes internal signal corresponding pads which correspond to the internal signal pads 6 and are wired to the glass substrate I/O pad 12, and reference numeral 17 denotes an emulator module having the microcomputer 2 mounted on the glass substrate 11.

The following will discuss the emulator module having the above configuration.

First, the microcomputer 2 having the microcomputer I/O pads 5 and the internal signal pads 6 is formed. And then, the glass substrate 11 having the microcomputer I/O corresponding pads 13 and the internal signal corresponding pads 14 is formed. The microcomputer I/O corresponding pads 13 correspond to the microcomputer I/O pads 5 and the internal signal corresponding pads 14 correspond to the internal signal pads 6, and the pads are each wired to the glass substrate I/O pad 12. Finally, the microcomputer 2 is mounted onto the glass substrate 11 and the emulator module 17 is formed. According to such a configuration, the emulator module 17 can input and output signals to the microcomputer I/O pads 5 via the glass substrate I/O pad 12. Additionally, since the glass substrate I/O pad 12 and the internal signal pads 6 are connected to each other, it is possible to monitor and control internal signals of the microcomputer 2, and emulation can be performed on the microcomputer 2.

In FIG. 4, reference numeral 2 denotes a microcomputer, reference numeral 5 denotes microcomputer I/O pads which are I/O pads of the microcomputer 2, reference numeral 6 denotes internal signal pads allowing input and output of internal signals of the microcomputer 2, reference numeral 18 denotes an emulator controlling LSI, reference numeral 19 denotes an I/O pad of the emulator controlling LSI that is an I/O pad of the emulator controlling LSI 18, reference numeral 4 denotes an emulation part formed in a circuit region of the emulator controlling LSI 18, reference numeral 13 denotes microcomputer I/O corresponding pads which correspond to the microcomputer I/O pads 5 and are wired to the I/O pads 19 of the emulator controlling LSI, and reference numeral 14 denotes internal signal corresponding pads which correspond to the internal signal pads 6 and are wired to the emulation part 4.

The following will discuss the emulator module having the above configuration.

First, the microcomputer 2 having the microcomputer I/O pads 5 and the internal signal pads 6 is formed. Subsequently, the emulator controlling LSI 18 having the microcomputer I/O corresponding pads 13 and the internal signal corresponding pads 14 is formed. The microcomputer I/O corresponding pads 13 correspond to the microcomputer I/O pads 5 and are wired to the I/O pads 19 of the emulator controlling LSI, and the internal signal corresponding pads 14 correspond to the internal signal pads 6 and are wired to the emulation part 4. Finally, the microcomputer 2 and the emulator controlling LSI 18 are bonded to each other to form the emulator module 17. Hence, the emulator module 17 can input and output signals to the microcomputer I/O pads 5 via the I/O pad 19 of the emulator controlling LSI. Moreover, since the emulation part 4 is connected to the internal signal pads 6, it is possible to monitor and control internal signals of the microcomputer 2, and emulation can be performed on the microcomputer 2.

However, the conventional evaluation chip can be used only as an emulation chip because wiring is performed on the mounted microcomputer. Thus, it is necessary to form a microcomputer for mass production in addition to the evaluation chip. Further, in the emulator module using the microcomputer for mass production and the glass substrate, a wiring distance is long between the emulator part and the internal signal of the microcomputer. Consequently, a high-speed operation is not possible. Additionally, in the case where the emulator module is formed using the microcomputer for mass production and the emulator controlling LSI, the emulator controlling LSI is generally shared for several kinds of microcomputers. Thus, each of the microcomputers suitably changes its wiring to form the emulator module. For this reason, an optimum layout is not available for each of the microcomputers, resulting in limits on a chip size and the number of terminals of the microcomputer.

### DISCLOSURE OF THE INVENTION

The present invention is devised to solve the above conventional problem. An object of the present invention is to provide an evaluation chip which can eliminate the need for developing a microcomputer for mass production in addition to an evaluation chip and which can operate at high speeds without any limits on a chip size and the number of terminals. Namely, the object of the present invention is to provide a semiconductor integrated circuit device whereby when a semiconductor integrated circuit serving as a main circuit and a semiconductor integrated circuit serving as an auxiliary circuit are integrated on a single semiconductor integrated circuit device, the semiconductor integrated circuit serving as a main circuit can be used separately so as to function by itself.

In order to attain the above object, the semiconductor integrated circuit device of the present invention, in which a first semiconductor integrated circuit serving as a main circuit and a second semiconductor integrated circuit serving as an auxiliary are formed on a single substrate and electrical connection is made between the first and second semiconductor integrated circuits to obtain a desired function, is characterized in that the first and second semiconductor integrated circuits are formed in semiconductor integrated circuit regions not overlapping each other and a first semiconductor integrated circuit region is surrounded by a scribed line. Here, the scribed line is an indentation formed for dividing an element on a silicon substrate. Even when the scribed line and the wiring intersects each other, an electrical characteristic of the wiring is not affected.

Moreover, the semiconductor integrated circuit device of the present invention is characterized by forming an evaluation chip in which the first semiconductor integrated circuit serving as a main circuit is used as a microcomputer and the second semiconductor integrated circuit serving as an auxiliary circuit is used as an emulation part.

According to this configuration, it is possible to integrate the semiconductor integrated circuit serving as a main circuit and the semiconductor integrated circuit serving as an auxiliary circuit on a single semiconductor integrated circuit device. Additionally, if necessary, the semiconductor integrated circuit serving as a main circuit can be cut along the scribed line so as to function by itself. Also, an internal signal of a semiconductor integrated circuit region can be monitored using a glass substrate. Consequently, it is possible to provide a semiconductor integrated circuit device which can operate at high speeds and to check the semiconductor integrated circuit region without any limits on a chip size and the number of terminals.

### BRIEF DESCRIPTION OF THE DRAWINGS

FIGS. 1a, 1b, 1c, and id are structural diagrams showing an evaluation chip, a wafer, a glass substrate, and an emulator module of the present invention;

FIG. 2 is a structural diagram showing a conventional evaluation chip;

FIGS. 3a, 3b, and 3c are structural diagrams showing a conventional emulator module including a microcomputer and a glass substrate; and

FIGS. 4a, 4b, and 4c are structural diagrams showing a conventional emulator module including a microcomputer and an emulator controlling LSI.

### DESCRIPTION OF THE EMBODIMENT

Referring to the drawings, the following will describe an evaluation chip as an embodiment of the present invention.

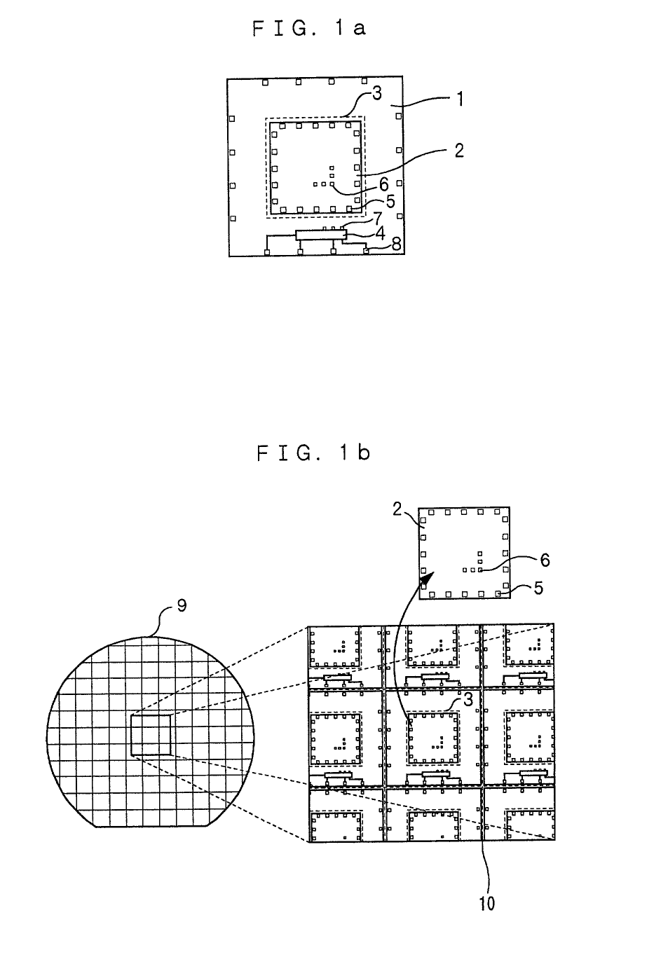

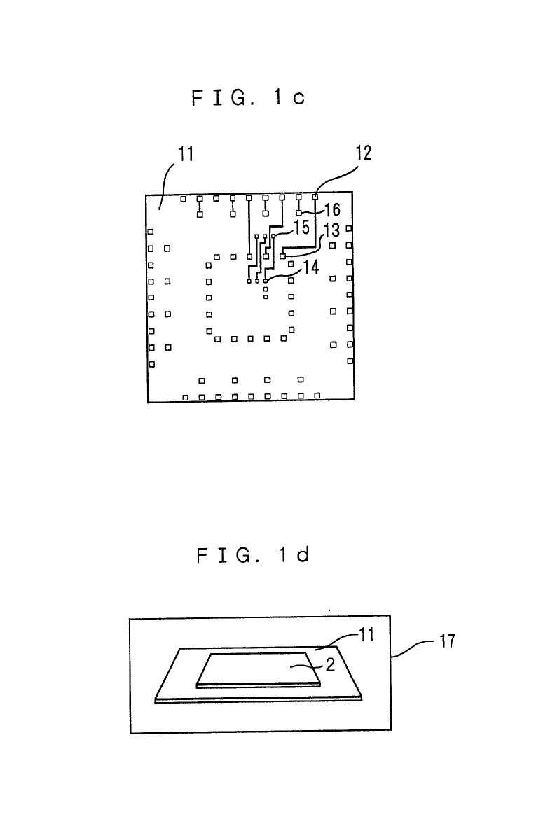

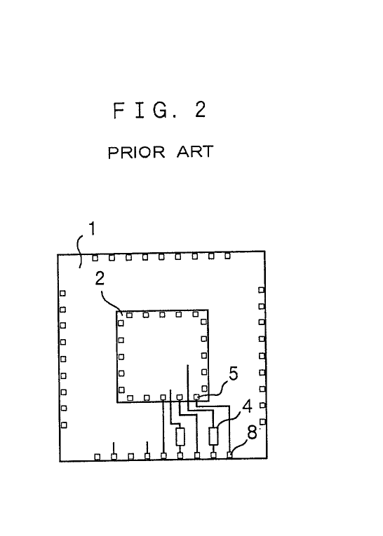

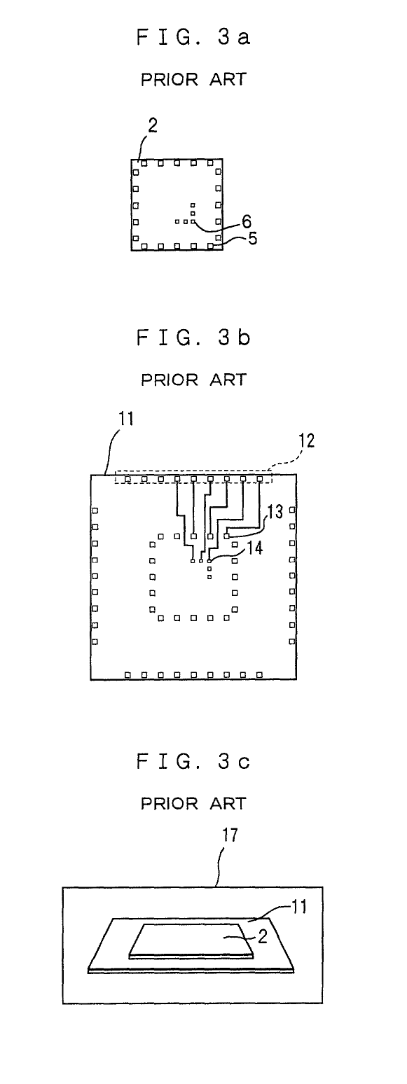

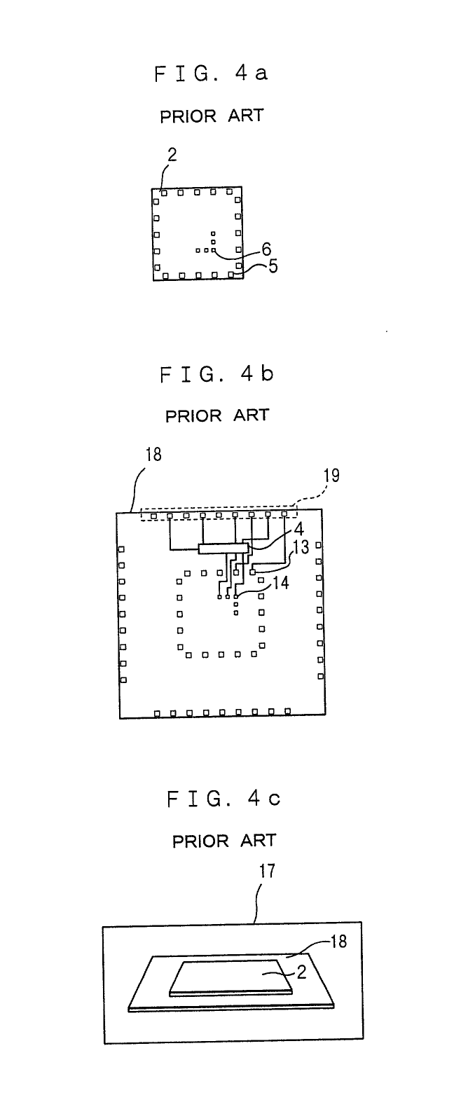

FIG. 1 is a structural diagram showing an evaluation chip according to an example of the present invention.

In FIG. 1a, reference numeral 1 denotes an evaluation chip, reference numeral 2 denotes a microcomputer included in the evaluation chip 1, reference numeral 3 denotes a microcomputer scribed line for scribing the microcomputer 2, reference numeral 4 denotes an emulation part included in the evaluation chip 1, reference numeral 5 denotes microcomputer I/O pads which are I/O pads of the microcomputer 2, reference numeral 6 denotes internal signal pads allowing input and output of internal signals of the microcomputer 2, reference numeral 7 denotes emulation part signal pads of the emulation part 4, and reference numeral 8 denotes evaluation chip I/O pads which are connected to the emulation part and are I/O pads of the evaluation chip 1.

Further, in FIG. 1b, reference numeral 9 denotes a wafer on which the evaluation chips 1 are spread, and reference numeral 10 denotes an evaluation chip scribed line which is a scribed line of the evaluation chips 1 on the wafer 9.

Moreover, in FIG. 1c, reference numeral 11 denotes a glass substrate for mounting the evaluation chip 1, reference numeral 12 denotes glass substrate I/O pads which are I/O pads of the glass substrate, reference numeral 13 denotes microcomputer I/O corresponding pads which correspond to the microcomputer I/O pads 5 and are wired to the glass substrate I/O pads 12, reference numeral 14 denotes internal signal corresponding pads of the glass substrate that correspond to the internal signal pads 6, reference numeral 15 denotes emulation part signal corresponding pads which correspond to the emulation part signal pads 7 and are wired to the internal signal corresponding pads 14, and reference numeral 16 denotes evaluation chip I/O corresponding pads which correspond to the evaluation chip I/O pads 8 and are wired to the glass substrate I/O pads 12.

Additionally, reference numeral 17 in FIG. 1d denotes an emulator module having the glass substrate 11 mounted on the evaluation chip 1.

The following will discuss the emulator module having the above configuration.

First, the mass-production microcomputer 2 having the microcomputer I/O pads 5 and the internal signal pads 6 is laid out separately. Subsequently, the microcomputer scribed line 3 for scribing the microcomputer 2 is formed around the separate layout of the microcomputer 2. Next, the emulation part 4 having the emulation part signal pads 7 is disposed around the microcomputer scribed line 3. And then, the evaluation chip I/O pads 8 are disposed around the emulation part 4 and are wired to the emulation part 4. Subsequently, the evaluation chip scribed line 10 for scribing the evaluation chip 1 is formed around the evaluation chip I/O pads 8, and layout is performed entirely on the evaluation chip 1. Finally, the evaluation chips 1 are spread using the entire layout of the evaluation chip 1, and the wafer 9 is formed.

### EMBODIMENT 1

Scribing is performed along a microcomputer scribed line 3, which is provided around a microcomputer 2 included in an evaluation chip 1 of a formed wafer 9. Since only the microcomputer 2 is taken out, it can be directly used as a microcomputer for mass production.

### EMBODIMENT 2

First, scribing is performed along an evaluation chip scribed line 10 provided around an evaluation chip 1 of a formed wafer 9, and the evaluation chip 1 including a microcomputer 2 is taken out. Next, a glass substrate 11 is formed, which has microcomputer I/O corresponding pads 13 corresponding to microcomputer I/O pads 5, internal signal corresponding pads 14 corresponding to internal signal pads 6, emulation part signal corresponding pads 15 corresponding to emulation part signal pads 7, and evaluation chip I/O corresponding pads 16 corresponding to evaluation chip I/O pads 8. In this case, the microcomputer I/O corresponding pads 13 are connected to the glass substrate I/O pads 12, the internal signal corresponding pads 14 are connected to the emulation part signal corresponding pads 15, and the evaluation chip I/O corresponding pads 16 are connected to the glass substrate I/O pads 12. Finally, the evaluation chip 1 is mounted on the glass substrate 11 to form an emulator module 17.

Therefore, the emulator module 17 can input and output signals to the microcomputer I/O pads 5 via the glass substrate I/O pads 12 and the microcomputer I/O corresponding pads 13. Further, since an emulation part 4 is connected to the internal signal pads 6 via the emulation part signal pads 7, the emulation part signal corresponding pads 15, and the internal signal corresponding pads 14, it is possible to monitor and control internal signals of the microcomputer 2, and emulation can be performed on the microcomputer 2.

According to the configurations of Embodiments 1 and 2, it is not necessary to develop a microcomputer for mass production in addition to an evaluation chip. Moreover, it is possible to realize an emulator module by using a glass substrate, thereby providing an evaluation chip which can operate at high speeds without any limits on a chip size and the number of terminals.

The above explanation described an evaluation chip. However, regarding a semiconductor integrated circuit device having the other functions as well, it is possible to integrate a semiconductor integrated circuit serving as a main circuit and a semiconductor integrated circuit serving as an auxiliary circuit in an internal region. Additionally, if necessary, the semiconductor integrated circuit serving as a main circuit can be used separately so as to function by itself.

1. A semiconductor integrated circuit device, in which a first semiconductor integrated circuit serving as a main circuit and a second semiconductor integrated circuit serving as an auxiliary circuit are formed on a single substrate and electrical connection is made between said first and second semiconductor integrated circuits to provide a desired function,
wherein said first and second semiconductor integrated circuits are formed in semiconductor integrated circuit regions not overlapping each other and said first semiconductor integrated circuit region is surrounded by a scribed line.

2. The semiconductor integrated circuit device according to claim 1, wherein an evaluation chip is configured in which said first semiconductor integrated circuit serving as a main circuit is used as a microcomputer and said second semiconductor integrated circuit serving as an auxiliary circuit is used as an emulation part.
